(19) United States
(12) Patent Application Publication
(10) Pub. No.: US 2008/0111130 A1
(43) Pub. Date: May 15, 2008

(54) ELECTRO-OPTIC DEVICE MANUFACTURING METHOD, ELECTRO-OPTIC DEVICE, LIQUID CRYSTAL DEVICE, ORGANIC ELECTROLUMINESCENT DEVICE, AND ELECTRONIC APPARATUS

(75) Inventor: Tomoyuki OKUYAMA, Chino-shi (JP)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 11/853,207

(22) Filed: Sep. 11, 2007

(30) Foreign Application Priority Data
Nov. 13, 2006 (JP) 2006-306255

(51) Int. Cl. H01L 51/00; H01L 21/00

(52) U.S. Cl. 257/40; 438/30; 257/E51.001; 257/E33.001

(57) ABSTRACT

An electro-optic device manufacturing method comprises providing a first partition on a substrate in a form of a pattern; depositing a metal material onto the substrate, forming a pixel electrode and a signal line on a top surface of the first partition, and forming a gate wire in an area surrounded by the first partition; after depositing, forming a second partition that partitions at least the a gate insulator formation area and a semiconductor layer formation area of which a section overlaps with the gate insulator formation area on the substrate; discharging functional liquid including a formation material for forming an insulator layer in the gate insulator formation area and forming a gate insulator; and after forming the gate insulator, discharging a functional liquid including a formation material for forming an organic semiconductor layer onto the semiconductor formation area and forming an organic semiconductor layer that crosses over the gate electrode and a section of the gate insulator and electrically connects the pixel electrode and the signal line.

The entire disclosure of Japanese Patent Application No. 2006-306255, filed Nov. 13, 2006 is expressly incorporated by reference herein.

### BACKGROUND OF THE INVENTION

1. Technical Field

The present invention relates to an electro-optic device manufacturing method, an electro-optic device, a liquid crystal device, an organic electroluminescent device, and an electronic apparatus.

2. Related Art

in recent years, organic semiconductor layers made of organic semiconductor material have been receiving attention. A reason for the attention is that such layers have the following advantages. The organic semiconductor layer may be manufactured through a process performed in extremely low temperatures compared to a non-organic semiconductor; a plastic substrate or film may be used; the organic semiconductor is flexible and lightweight; and a durable element can be manufactured. The element can be manufactured in a short amount of time through the use of simple methods, such as application of a solution or printing method (ink-jet method). As a result, processing costs and device costs can be reduced.

Therefore, it is a demanded that an organic semiconductor device including the organic semiconductor layer is formed using an ink-jet process. The semiconductor device is generally used as a switching element in, for example, an electro-optic device. The channel length (gate electrode width) is preferably short to enhance the characteristics of the semiconductor layer. However, in current technology, the channel length (gate electrode width) that can be formed using the ink-jet process is limited. Therefore, sufficient size reduction of the channel has been difficult.

Therefore, there is a method combining a photolithography process and an ink-jet process. In the method, a gate electrode requiring a fine pattern is formed by the photolithography process and an organic semiconductor layer is formed by the ink-jet process (for example, refer to JP-T-2005-531134).

JP-T-2005-531134 is an example of related art.

However, in the invention disclosed in the example, the channel length is shortened by a source electrode and a drain electrode being formed so as to mesh like a comb. Therefore, a parasitic capacitance is formed in an area in which the source or the drain electrode overlaps with the gate electrode. As a result, wiring delay occurs, thereby making the semiconductor unreliable.

### SUMMARY

An advantage of the present invention is to provide an electro-optic device manufacturing method, an electro-optic device, a liquid crystal device, an organic electroluminescent device, and an electronic apparatus that allow an organic semiconductor layer with higher reliability to be obtained when a droplet discharging method is used to form the organic semiconductor layer.

An electro-optic device manufacturing method according to an aspect of the invention includes the following procedures. A first partition is provided on a substrate in the form of a pattern. A metal material is deposited onto the substrate, a pixel electrode and a signal line are formed on the top surface of the first partition, and a gate wire is formed in an area surrounded by the first partition. After the metal material is deposited, a second partition is formed. The second partition partitions at least a gate insulator formation area and a semiconductor layer formation area of which a section overlaps with the gate insulator formation area on the substrate. Functional liquid including a formation material for forming an insulator layer is discharged onto the gate insulator formation area and the gate insulator is formed. After the gate insulator is formed, functional liquid including a formation material for forming an organic semiconductor layer is discharged onto the semiconductor layer formation area. An organic semiconductor layer that crosses over the gate electrode and a section of the gate insulator and electrically connects the pixel electrode and the signal line is formed.

In the electro-optic device manufacturing method of the present invention, as a result of the droplet discharging method, for example, the functional liquid discharged onto the semiconductor layer formation area becomes self-flowing (capillarity). The functional liquid can flow to the ends of a fine pattern so as to cross over the gate electrode, via the gate insulator. As a result, the channel length of the semiconductor layer in an area intersecting with the gate wire can be shortened. A source region and a drain region formed on both sides of a channel area do not intersect (gate overlap) with the gate electrode (gate wire), as did in the past. A highly reliable electro-optical device in which problems such as wiring delay are prevented can be provided.

In the electro-optic device manufacturing method, a preferred aspect of the invention is that an auxiliary wiring is formed on at least one area of the surface of the substrate on which the gate wire is formed, as a procedure performed before the first partition is formed.

As a result of the configuration, even when the gate wire formed in the area partitioned by the first partition is fine, the voltage drop of the gate wire can be suppressed because a part of the gate wire is connected to the auxiliary wiring.

In the electro-optic device manufacturing method, a preferred aspect of the invention is that, in the procedure for forming the second partition, the second partition is partitioned and formed so as to face a portion of the pixel electrode. A capacitor wire formation area included in a capacitor that holds the electric charge of the pixel electrode is formed. In the procedure for forming the gate insulator, the functional liquid is also discharged onto the capacitor wire formation area and an inter-layer insulator included in the capacitor is formed. After the organic semiconductor layer is formed, conducting functional liquid is discharged onto the capacitor wire formation area, and the capacitor is formed. The capacitor having a laminated structure in which the pixel electrode, the inter-layer insulator, and the capacitor wire are layered is formed.

As a result of the configuration, the capacitor that holds the electric charge of the pixel electrode can be formed by the droplet discharging method. An electro-optic device that can hold data can be provided. The electro-optic device can be favorably used as a liquid crystal device.

At this time, a liquid pooling section that is wider than those of the other areas can be provided in at least one area among the gate insulator formation area, the semiconductor layer formation area, and the capacitor wire formation area. The functional liquid can be discharged onto the liquid pooling section.

As a result, the functional liquid discharged onto the liquid pooling section by the droplet discharging method can become self-flowing (capillarity). The functional liquid can flow into minute areas of the gate insulator formation area and the semiconductor layer formation area.

In the electro-optic device manufacturing method, a preferred aspect of the invention is that the inner wall of the first partition serving as a gate wire formation area has an angled surface that forms an acute angle to the top surface of the substrate.

As a result of the configuration, the top surface side of the first partition serving as the gate wire formation area is in the shape of eaves. Therefore, the amount of deposited material reaching the inner walls of the first partition is reduced. As a result, the conduction between the pixel electrode and the signal line formed on the first partition and the gate wire formed in the area surrounded by the first partition can be prevented. The acute angle of the angled surface is preferably equal to or less than 80 degrees and equal to or more than 75 degrees.

An electro-optic device according to an aspect of the invention includes a substrate, a first partition, a gate electrode, a gate insulator, a signal line, a pixel electrode, and a second partition. The first partition is provided on the substrate. The gate electrode is provided in a groove formed by the first partition. The gate insulator covers the gate electrode. The signal line and the pixel electrode are provided on the top surface of the first partition. The second partition is provided on the first partition so as to cross over a section of the groove. An organic semiconductor layer is provided in a semiconductor layer formation area surrounded by the second partition. The organic semiconductor layer crosses over the gate insulator, electrically connects the signal line and the pixel electrode, and is formed by the droplet discharging method.

In the electro-optic device of the invention, for example, because the formation material for forming the organic semiconductor layer is discharged onto the semiconductor layer formation area surrounded by the second partition, the formation material for forming the organic semiconductor layer becomes self-flowing (capillarity) and the organic semiconductor layer crossing over the gate electrode can have a fine pattern. As a result, the semiconductor layer intersecting with the gate line or, in other words, the channel length in the channel area becomes short. The source region and the drain region formed on both sides of the channel area do not intersect (gate overlap) with the gate electrode. Therefore, a highly reliable electro-optic device in which problems, such as wiring delay, are prevented can be obtained.

In the electro-optic device, a preferred aspect of the invention is that a capacitor that holds the electric charge of the pixel electrode is formed in an area surrounded by the second partition. The capacitor includes a capacitance electrode and an insulator layer. The capacitance electrode is formed from a portion of the capacitor wire and a portion of the pixel electrode. The insulator layer is provided between capacitance electrodes.

In the configuration, a capacitor that holds the electric charge of the pixel electrode is provided. Therefore, data can be held. The invention can be favorably applied to the liquid crystal display in particular.

In the electro-optic device, a preferred aspect of the invention is a liquid pooling section that is wider than those of other areas is formed in a section of the semiconductor layer formation area.

In the configuration, when the semiconductor layer is formed by the droplet discharging method, the channel length can be successfully shortened, as described above, by the formation material for forming the organic semiconductor layer being discharged onto the liquid pooling section.

A liquid crystal device according to an aspect of the invention is a liquid crystal device in which a liquid crystal layer is sandwiched between a pair of substrates disposed facing each other, in which one substrate among the pair of substrates includes a first partition, a gate electrode, a signal line, a pixel electrode, and a second partition. The gate electrode is disposed in a groove formed by the first partition. The signal line and the pixel electrode are provided on the top surface of the first partition. The second partition is laminated onto the first partition. In the other substrate among the pair of substrates, an organic semiconductor layer that crosses over a gate insulator covering the gate electrode and electrically connects the signal line and the pixel electrode is provided. In another area surrounded by the second partition, the insulator layer and the capacitance electrode are layered. As a result, the capacitor that holds the electric charge of the pixel electrode is formed.

In the liquid crystal device of the invention, the formation material forming the organic semiconductor layer becomes self-flowing (capillarity). The organic semiconductor layer that crosses over the gate electrode is formed from fine patterns. The semiconductor layer intersecting with the gate wire or, in other words, the channel length in the channel area becomes shortened. The gate electrode (gate wire) does not intersect (gate overlap) with the source region and the drain region formed on both sides of the channel area, as did in the past. A highly reliable liquid crystal device in which problems such as wiring delay are prevented can be obtained. By the capacitor holding the electric charge of the pixel electrode being included, the liquid crystal device can hold data and is highly reliable.

An organic electroluminescent device according to an aspect of the invention is an organic electroluminescent device in which an organic light-emitting layer is provided between a pair of electrodes provided on a substrate. The substrate includes a first partition, a gate electrode, a signal line, a pixel electrode, and a second partition. The gate electrode is disposed in a groove formed by the first partition. The signal line and the pixel electrode are provided on the top surface of the first partition. The second line is laminated onto the first partition. In one area surrounded by the second partition, an organic semiconductor layer that crosses over a gate insulator covering the gate electrode and electrically connects the signal line and the pixel electrode is provided. In another area surrounded by the second partition, the insulator layer and the capacitance electrode are laminated onto the pixel electrode. As a result, a capacitor that holds the electric charge of the pixel electrode is formed.

In the organic electroluminescent device of the invention, the formation material forming the organic semiconductor layer becomes self flowing (capillarity). The organic semiconductor layer that crosses over the gate electrode is formed from fine patterns. The semiconductor layer intersecting with the gate wire or, in other words, the channel length in the channel area becomes shortened. The gate electrode (gate wire) does not intersect (gate overlap) with the source region and the drain region formed on both sides of the channel area, as did in the past. A highly reliable organic electroluminescent device in which problems such as wiring delay are prevented can be obtained. By the capacitor holding the electric charge of the pixel electrode being included, the organic electroluminescent device can hold data and is highly reliable.

The electronic apparatus of the invention includes the electro-optic device obtained by the above-described electro-optic device manufacturing method, the above-described electro-optic device, the above-described liquid crystal display, or the above-described organic electroluminescent device.

The electronic apparatus of the invention includes the electro-optic device, the liquid crystal device, or the organic electroluminescent device that are highly reliable. As described above, in the electro-optic device, the liquid crystal device, and the organic electroluminescent device, the gate length is short and problems, such as writing delay caused by gate overlapping, can be prevented. As a result, the electronic apparatus itself has high display quality and is highly reliable.

### BRIEF DESCRIPTION OF THE DRAWINGS

The invention will be described with reference to the accompanying drawings, wherein like numbers reference like elements.

FIG. 1 is a diagram of an example of a droplet discharging device used in an electro-optic device manufacturing method.

FIG. 2 is a diagram explaining a principle of liquid material dischargeion according to a piezo method.

FIG. 3 is a diagram, explaining a procedure performed to manufacture an electrophoretic device.

FIG. 4 is a diagram explaining a procedure performed to manufacture an electrophoretic device following FIG. 3.

FIG. 5 is a diagram explaining a procedure performed to manufacture an electrophoretic device following FIG. 4.

FIG. 6 is a diagram explaining a procedure performed to manufacture an electrophoretic device following FIG. 5.

FIG. 7 is a diagram explaining a procedure performed to manufacture an electrophoretic device following FIG. 6.

FIG. 8 is a diagram explaining a procedure performed to manufacture an electrophoretic device following FIG. 7.

FIG. 9 is a diagram explaining a procedure performed to manufacture an electrophoretic device following FIG. 8.

FIG. 10 is a diagram explaining a procedure performed to manufacture an electrophoretic device following FIG. 9.

FIG. 11 is a diagram of a configuration of an electrophoretic device according to an embodiment of the present invention.

FIG. 12 is a diagram of an equivalent circuit of a plurality of dots disposed in the form of a matrix.

FIG. 13 is a diagram showing an overall configuration of a liquid crystal device according to an embodiment of the invention.

FIG. 14 is a schematic diagram of a cross-section taken along line A-A in FIG. 13.

FIG. 15 is a cross-sectional view of a configuration of an organic EL device according to an embodiment of the invention.

FIG. 16 is a perspective view of a portable phone according to an embodiment of an electrical apparatus.

### DESCRIPTION OF EXEMPLARY EMBODIMENTS

Embodiments of the invention will be described.

### First Embodiment

An embodiment of the invention will be below described, with reference to the drawings. The embodiment described below is a part of the embodiments of the invention. The invention is not limited to the embodiment. In each drawing used in the descriptions below, magnification of each layer and each component is changed accordingly for each layer and each component so that each layer and each component can be sized to a degree recognizable in the drawing.

Droplet Discharging Device

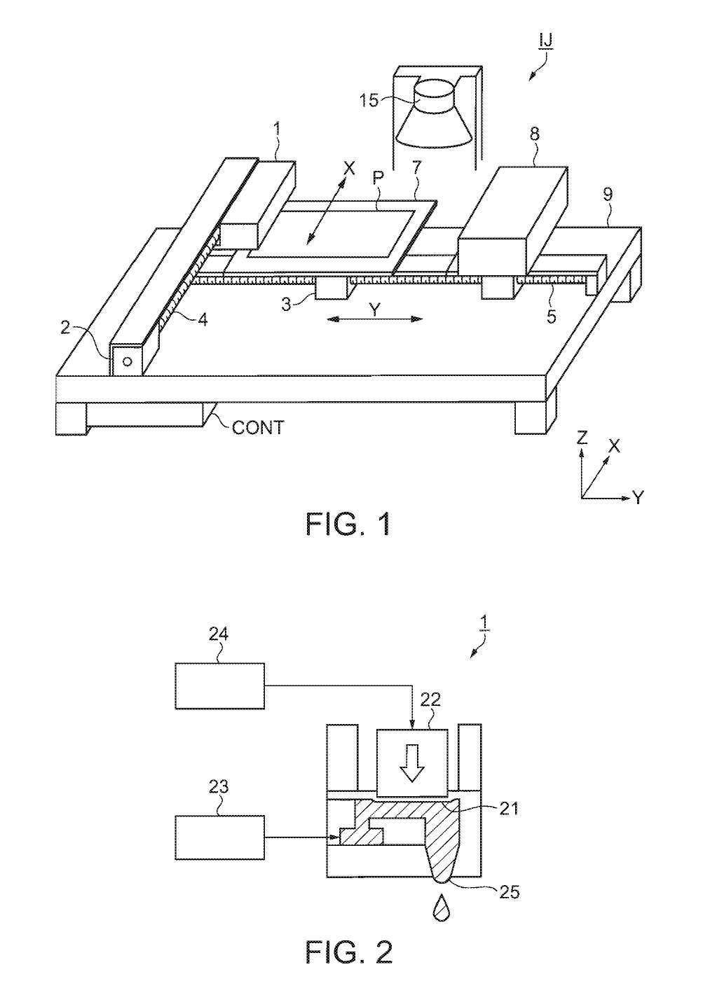

First, before an electro-optic device manufacturing method is described, a droplet discharging device used for forming the electro-optic device will be described with reference to FIG. 1. FIG. 1 is a perspective view of a configuration of a droplet discharging device fink-jet device) IJ. The droplet discharging device IJ disposes liquid materials onto a substrate using a droplet discharging method and is an example of a device used in the electro-optic device manufacturing method. As described in detail hereafter, the droplet discharging device IJ is used when an organic semiconductor layer, a gate insulator, a capacitor wire, and the like are formed on a substrate forming the electro-optic device.

The droplet discharging device JJ includes a droplet discharging head 1, an X-axis direction driving axis 4, a Y-axis direction guide axis 5, a controller CONT, a state 7, a cleaning mechanism 8, a base 9, and a heater 15.

The stage 7 supports a substrate 48, described hereafter. The droplet discharging device IJ sets ink (liquid material) on the substrate 48. The stage 7 includes a fixing mechanism (not shown) that fixes the substrate 48 in a reference position.

The droplet discharging head 1 is a multi-nozzle-type droplet discharging head including a plurality of discharging nozzles. A longitudinal direction of the droplet discharging head 11 and a Y-axis direction match. The plurality of discharging nozzles are uniformly spaced and aligned in the Et-axis direction on the undersurface of the droplet discharging head 1. The discharging nozzle of the droplet discharging head 1 discharges ink that includes conductive particles, described above, onto the substrate 48. The stage 7 supports the substrate 48.

An X-axis direction driving motor 2 is connected to the X-axis direction driving axis 4. The X-axis direction driving motor 2 is a stepping motor or the like. When an X-axis direction driving signal is supplied from the controller CONT, the X-axis direction driving motor 2 rotates the X-axis direction driving axis 4. When the X-axis direction driving axis 4 is rotated, the droplet discharging head 1 moved in the X-axis direction.

The Y-axis direction guide axis 5 is fixed onto the base 9 so as not to move. The stage 7 includes a Y-axis direction driving motor 3. The Y-axis direction driving motor 3 is a stepping motor or the like. When a Y-axis direction driving signal is supplied from the controller CONT, the stage 7 moves in the Y-axis direction.

The controller CONT supplies the droplet discharging head 1 with voltage for controlling the dischargeion of the droplets. The controller CONT supplies the X-axis direction driving motor 2 with a driving pulse signal that controls the movement of the droplet discharging head 1 in the X-axis direction. The controller CONT also supplies the Y-axis direction driving motor 3 with a driving pulse signal that controls the movement of the stage 7 in the Y-axis direction.

The cleaning mechanism 8 cleans the droplet discharging head 1. The cleaning mechanism 8 includes a Y-axis direction driving motor (not shown). As a result of drive from the Y-axis direction driving motor, the cleaning mechanism 8 moves along the Y-axis direction guide axis 5. The controller CONT also controls the movement of the cleaning mechanism 8.

The heater 15 is used to heat-process the substrate 48 by lamp annealing. The heater 15 evaporates and dries a solvent included in the liquid materials applied to the substrate 48. The controller CONT also controls the power ON and OFF of the heater 15.

The droplet discharging device IJ discharges droplets onto the substrate 48, while relatively scanning the droplet discharging head 1 and the stage 7 supporting the substrate 48. In the description below, the X-axis direction is a scanning direction. The Y-axis direction perpendicular to the X-axis direction is a non-scanning direction. Therefore, the discharging nozzles of the droplet discharging head 1 are uniformly spaced and aligned in the Y-axis direction that is the non-scanning direction. In FIG. 1, the droplet discharging head 1 is disposed at a right angle to a traveling direction of the substrate 48. However, the angle of the droplet discharging head 1 may be adjusted to intersect with the traveling direction of the substrate 48. In this case, the pitch between the nozzles can be adjusted by the adjustment of the droplet discharging head 1 angle. The droplet discharging device IJ may be configured so that the distance between the substrate 48 and the nozzle surface can be arbitrarily adjusted.

FIG. 2 is a diagram explaining a principle of liquid material dischargeion according to a piezo method. In FIG. 2, a piezo element 22 is provided adjacent to a liquid chamber 21. The liquid chamber 21 holds the liquid materials (wiring pattern ink and functional liquid). The liquid materials are supplied to the liquid chamber 21 via a liquid material supplying system 23. The liquid material supplying system 23 includes a material tank that holds the liquid materials.

The piezo element 22 is connected to a driving circuit 24. Voltage is applied to the piezo element 22, via the driving circuit 24. The piezo element 22 becomes deformed. As a result, the liquid chamber 21 becomes deformed, and the liquid materials are discharged from a nozzle 25. In this case, the degree by which the piezo element 22 is deformed is controlled by the value of the applied voltage being changed. The speed at which the piezo element 22 is deformed is controlled by the frequency of the applied voltage.

As the principle of liquid material dischargeion, various known technologies can be used, in addition to the piezo method in which the ink is discharged using a piezo element that is the above-described piezoelectric element. For example, a bubble method can be used in which the liquid materials are discharged by a bubble created by heating the liquid materials. Among the technologies, the liquid material is not heated in the piezo method used according to the embodiment of the invention. This is advantageous in that the composition of the material and the like are not affected.

Here, functional liquid L is formed from a solvent (carrier fluid) in which dispersion liquid, organic semiconductor material, and high polymer dielectric material are dispersed. In the dispersion liquid, conductive particles are dispersed in carrier fluid.

As the conductive particles, metal particles including any of, for example, gold, silver, copper, palladium, and nickel are used. In addition to the metal particles, oxides of the metal particles, and conductive polymer and superconductive particles are used. The conductive particles can also be used with the surfaces thereof coated with organic matter to enhance dispersion. Coating material that coats the surfaces of the conductive particles is, for example, an organic solvent and citric acid. The organic solvent is, for example, xylene and toluene. The particle size of the conductive particle is preferably equal to or more than 1 nm and equal to or less than 0.1 μm. If the particle size is more than 0.1 μm, the nozzles of the droplet discharging head, described hereafter, may become blocked. If the particle size is less than 1 nm, the volume ratio of the coating agent to the conductive particle increases. The percentage of organic matter within the resulting film becomes excessive.

As the organic semiconductor material, both low-molecular-type organic semiconductor material and polymer organic semiconductor material can be used. As polymeric dielectric material, various materials can be used without particular limitations, as long as the material has insulating properties. Both organic material and non-organic material can be used.

The carrier fluid is not particularly limited as long as the above-described material can be dispersed within the carrier fluid and agglutination does not occur. For example, in addition to water, alcohols such as methanol, ethanol, propanol, and butanol can be used. Hydrocarbon compounds such as n-heptane, n-octane, decane, dodecane, tetradecane, toluene, xylene, cymene, durene, indene, dipentene, tetrahydronaphthalene, decahydronaphthalene, and cyclohexylbenzene can also be used. Ether compounds such as ethylene glycol dimethyl ether, ethylene glycol diethyl ether, ethylene glycol methyl ethyl ether, diethylene glycol dimethyl ether, diethylene glycol diethyl ether, diethylene glycol methyl ethyl ether, 1,2-dimethoxyethane, bis(2-methoxyethyl)ether, and p-dioxane can also be used. Polar compounds such as propylene carbonate, γ-butyrolactone, N-methyl-2-pyrrolidone, dimethylformamide, dimethyl sulfoxide, and cyclohexanone are given as examples. Among these, in terms of particle dispersion, dispersion liquid stability, and easiness of application to the droplet discharging method (inkjet method), water, alcohols, hydrocarbon compounds, and ether compounds are preferable. More preferably, the carrier fluid is water or hydrocarbon compounds.

Electro-optic device manufacturing method

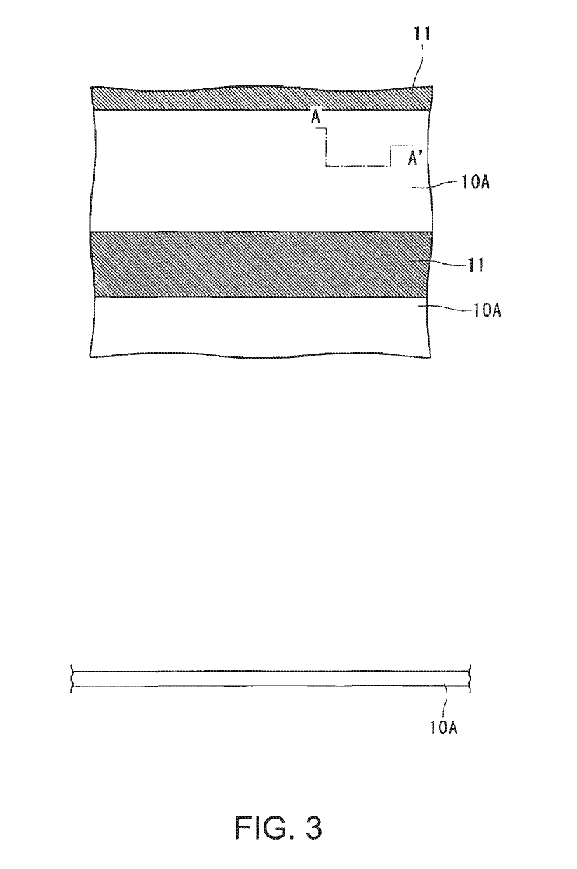

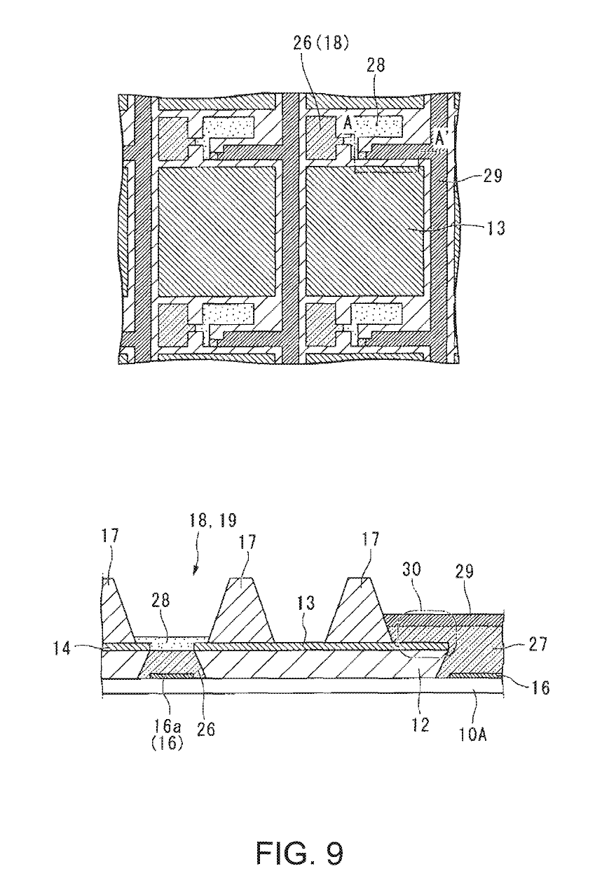

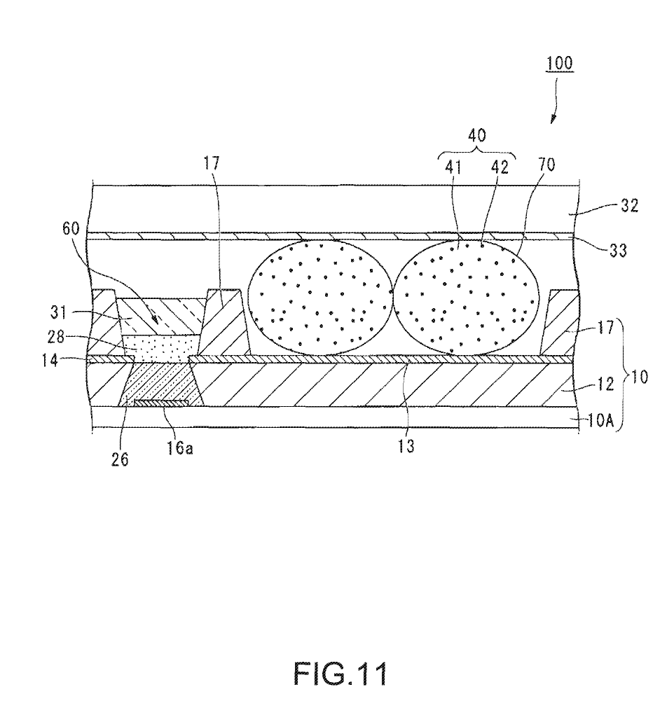

Next, as a manufacturing method of an electro-optic device using the above-described droplet discharging device IJ according to an embodiment of the invention, procedures for manufacturing an electrophoretic device 100 (see FIG. 11) will be described with reference to the drawings. The manufacturing method according to the embodiment of the invention includes forming a thin-film transistor (TFT) substrate 10 included in the electrophoretic device 100, shown in FIG. 11. Other procedures are the same as conventional methods. Therefore, detailed explanations thereof are omitted. In FIGS. 3 to 10, hereafter, the top drawing is a planar view corresponding to an area in which a pixel area of the electrophoretic device 100 is formed. The bottom drawing is a partial cross-sectional view taken along line A-A′ in the top drawings.

First, a substrate main body 10A is prepared as a base material for forming the TFT substrate 10. A glass substrate, a quartz substrate, and the like having light-transmittance is used as the substrate main body 10A. Then, as shown in FIG. 3, auxiliary wiring 11 is formed on the substrate main body 10A. The auxiliary wiring 11 is formed from gold (Au) that is the same material as a gate wire formed in a later procedure. As a method of forming the auxiliary wiring 11, for example, patterning by a mask-evaporation method or a photolithography process, and the like can be given.

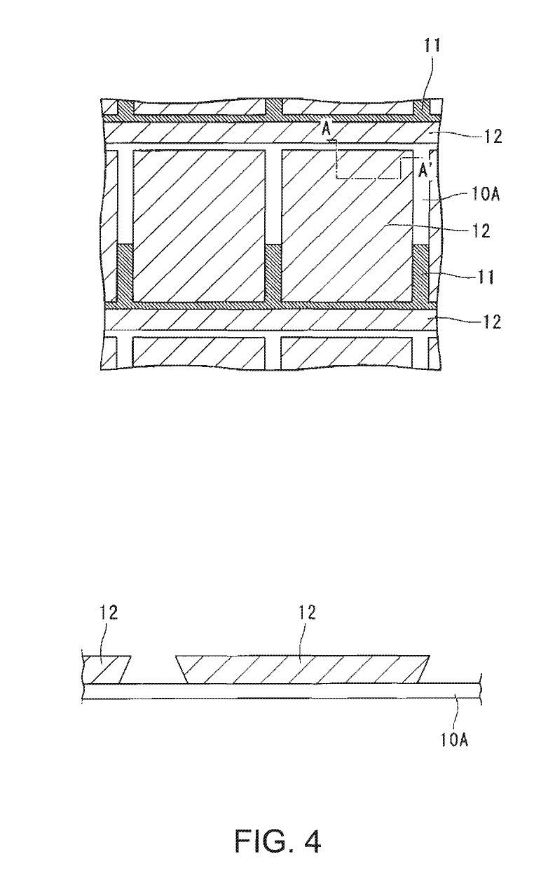

Next, as shown in FIG. 4, a first partition 12 is formed in a pattern on the substrate main body 10A. Specifically, a negative resist, serving as a material used to form the first partition 12, is applied to the substrate. After exposure using a mask, the negative resist is developed. As a result, the area that has not been exposed is dissolved by the developing fluid, and the first partition 12 is formed in a pattern.

The pattern is an area in which the gate wire is formed in a later procedure. The pattern is roughly ladder-shaped from a planar perspective. On the bottom surface of the area (also referred to, hereinafter, as a gate formation area) partitioned (surrounded) by the first partition 12, the top surface of the substrate main body 10A and the auxiliary wiring 11 are in an exposed state. An inner wall surface 12a of the first partition 12 that forms the gate wire formation area has an angled surface that forms an acute angle to the top surface of the substrate main body 10A. The top surface side of the first partition 12 extends to the bottom surface in the shape of eaves. The acute angle of the angled surface is preferably equal to or less than 80 degrees and, more preferably, equal to or less than 75 degrees.

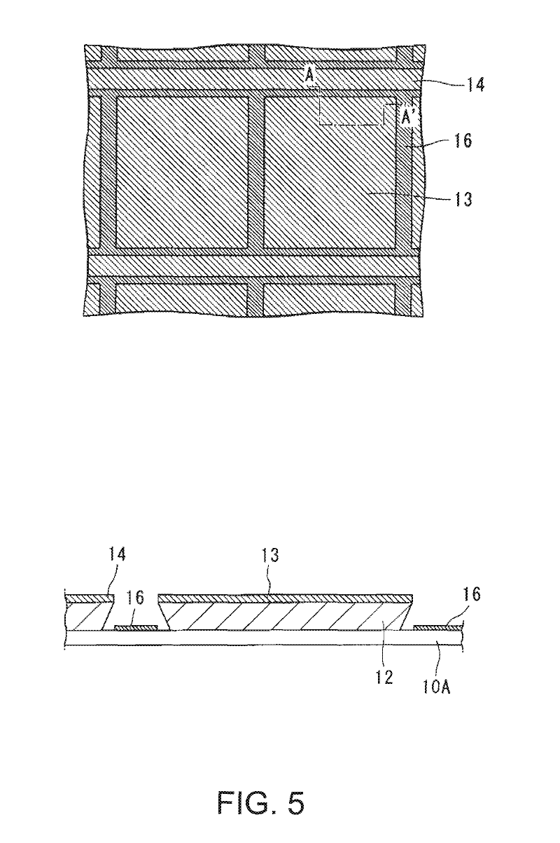

Next, as shown in FIG. 5, a metal material is deposited onto the substrate main body 10A. According to the embodiment, the metal material is gold. As a result, a pixel electrode 13 and a signal line 14 are formed on the top surface of the first partition 12.

The gate wire is formed by the gold deposited in the gate wire formation area surrounded by the first partition 12. At this time, as shown in FIG. 3, the auxiliary wiring 11 is formed in the gate wire formation area. A portion of a gate wire 16 is connected to the auxiliary wiring 11. As a result, even when the gate wire 16 formed in the gate wire formation area is fine, voltage drop of the gate wire 16 is suppressed.

At this time, the top surface of the first partition 19 forming the gate wire formation area is in the shape of eaves. Therefore, the amount of deposited material (gold) reaching the inner wall surface 12a of the first partition 12 is reduced. As a result, conduction between the pixel electrode 13 and the signal line 14 formed on the first partition 12 and the gate wire 16 formed in the gate wire formation area can be prevented with certainty.

Specifically, as shown in FIG. 5, a rectangular pixel electrode 13 is formed on the top surface of the first partition 12. The four sides of the first partition 12 are surrounded by the gate wire formation area. The signal line 14 is formed on the first partition 12 that extends between pixel electrodes 13 adjacent in the vertical direction in the diagram.

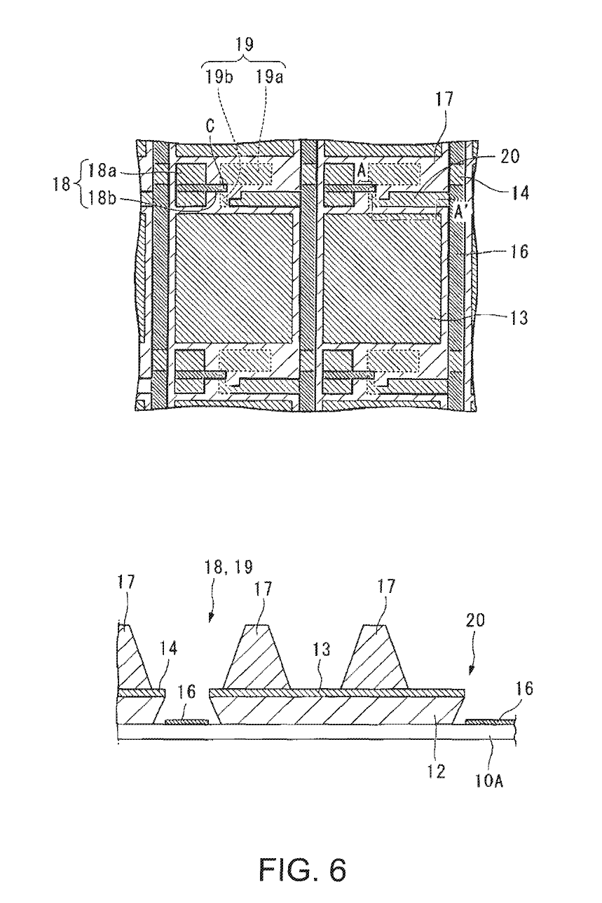

After the deposition procedure, a second partition 17 is formed on the substrate main body 10A, as shown in FIG. 6. Specifically, a positive resist, serving as a material used to form the first partition 12, is applied to the substrate. After exposure using a mask, the positive resist is developed. As a result, the area that has been exposed is dissolved by the developing fluid, and the second partition 17 is formed in a pattern.

The second partition 17 partitions a gate insulator formation area 18 and a semiconductor layer formation area 19. In the gate insulator formation area 18, the gate insulator is formed by the droplet discharging device IJ in a procedure described hereafter. In the semiconductor layer formation area 19, the semiconductor layer is formed by the droplet discharging device IJ in a procedure similarly described hereafter.

The gate insulator formation area 18 and the semiconductor layer formation area 19 includes liquid pooling sections 18a and 19a, and fine patterned sections 18b and 19b. The liquid pooling sections 18a and 19a are used for discharging the functional liquids (liquid material) discharged from the droplet discharging head 1 of the droplet discharging head IJ. The fine patterned sections 18b and 19b extend from the liquid pooling sections 18a and 19a. As a result of this configuration, the functional liquid discharged from the droplet discharging head 1 into the liquid pooling sections 18a and 19a can become self-flowing (capillarity). The functional liquid can flow into minute areas of the gate insulator formation area 18 and the semiconductor layer formation area 19.

The fine patterned sections 18b and 19b of the gate insulator formation area 18 and the semiconductor layer formation area 19 intersect (overlap) at the section indicated by C in the diagram. This intersection forms a channel area of the organic TFT. In other words, according to the embodiment, the channel length is the width of the fine patterned section 18b in the gate insulator formation area 18.

According to the embodiment, in a procedure for forming the second partition 17, the second partition 17 is partitioned and formed so as to face a portion of the pixel electrode 13. A capacitor wire formation area 20 for providing a Capacitor that holds the electric charge of the pixel electrode 13 is formed. As do the other areas (the gate insulator formation area 18 and the semiconductor layer formation area 19), the capacitor wire formation area 20 includes two areas, an area partitioned by the first partition 12 and an area partitioned by the second partition 17. The capacitor wire formation area 20 is formed consecutively with the semiconductor layer formation area 19. In the capacitor wire formation area 20, the wire width becomes narrow near a section connecting the capacitor wire formation area 20 with the semiconductor layer formation area 19, as shown in FIG. 6.

Therefore, the capacitor wire formation area 20 described hereafter has a stepped structure. The capacitor has a laminated structure. In the laminated structure, the pixel electrode 13 formed on the upper level of the stepped structure, an inter-layer insulator, and the capacitor wire are layered. The inter-layer insulator is formed by a procedure described hereafter. Therefore, through adjustment of the width and height of the first partition 12 and the second partition 17 forming the stepped structure, a capacitor of a desired size can be formed.

According to the embodiment of the invention, the above-described liquid pooling section is not provided because the pattern width of the capacitor wire formation area 20 is roughly even. However, the invention is not limited thereto. The liquid pooling section can be provided in the capacitor wire formation area 20, as is provided in the gate insulator formation area 18 and the semiconductor layer formation area 19.

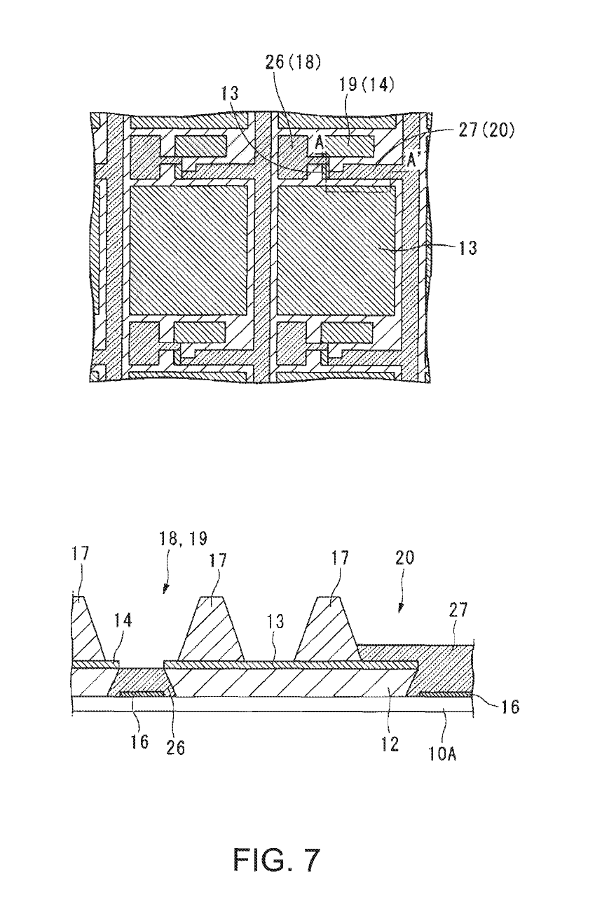

Next, the functional liquid including the gate insulator formation material is discharged into the liquid pooling section 18a of the gate insulator formation area 18 by the droplet discharging device IJ. As shown in FIG. 7, a gate insulator 26 is formed. Various materials can be used as a material forming the gate insulator 26 without particular limitations, as long as the material has insulating properties. Either an organic material or a non-organic material can be used.

For example, know organic materials used to form the gate insulator are polymeric film and parylene film. The polymeric film is, for example, polymethyl methacrylate, polyvinyl phenol, polyimide, polystyrene, polyvinyl alcohol, and polyvinyl acetate. Non organic materials are metal oxides and combined metal oxides. The metal oxides are, for example, silicon oxide, silicon nitride, aluminum oxide, and tantalum oxide. The combined metal oxides are, for example, barium strontium titanate and lead zirconium titanate. One type among these materials can be used. Alternatively, two or more types can be used in combination.

As described above, when the second partition 17 is formed, the capacitor wire formation area 20 is formed. According to the embodiment, in the procedure for forming the gate insulator 26, the formation material (functional liquid) for forming the inter-layer insulator is discharged onto the capacitor wire formation area 20. A first inter-layer insulator layer (inter-layer insulator) 27 that forms the capacitor holding the electric charge of the pixel electrode 13 is formed. The first inter-layer insulator layer 27 is formed from the same material as the gate insulator 26. At this time, in the capacitor wire formation area 20, the wire width becomes narrow near the section connecting the capacitor wire formation area 20 with the semiconductor layer formation area 19, as shown in FIG. 6. Therefore, the insulating material discharged onto the capacitor wire formation area 20 can be prevented from self-flowing into the semiconductor layer formation area 19. The area over which the wire width is narrowed is preferably as long as possible. As a result, connection problems between the semiconductor layer and the pixel electrode 13, disposed in a later procedure, can be prevented with certainty.

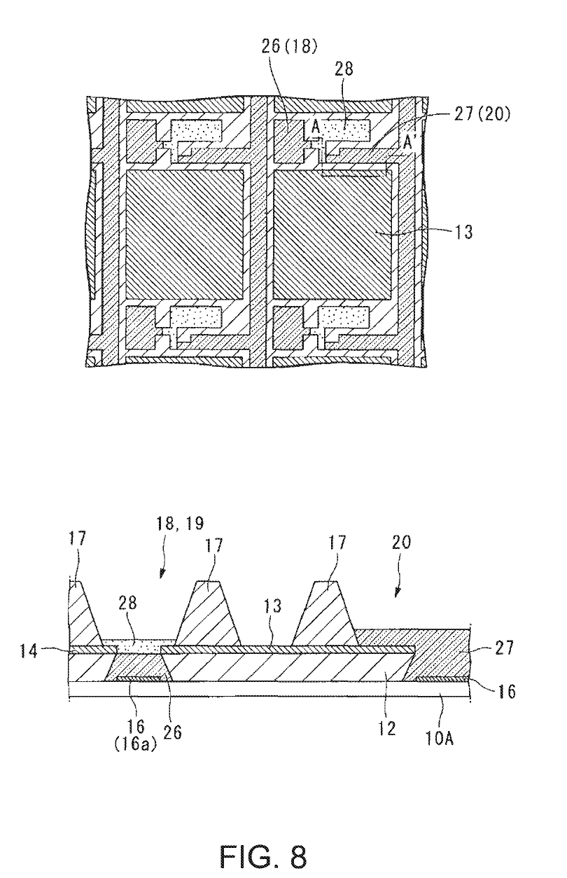

After the gate insulator 26 and the first inter-layer insulator 27 are formed, the formation material (functional liquid) of the organic semiconductor layer is discharged onto the liquid pooling section 19a of the semiconductor layer formation area 19, by the droplet discharging device IJ. The functional liquid discharged onto the liquid pool section 19a is self flowing (capillarity). The functional liquid flows into the fine pattered section 19b shown in FIG. 6 and crosses over the gate insulator 26. In the semiconductor formation area 19, the signal line 14 and the pixel electrode 13 are disposed opposing each other, with the gate wire 16 therebetween (see FIG. 7). In other words, by the above-described procedure shown in FIG. 8, an organic semiconductor layer 28 that electrically connects the pixel electrode 13 and the signal line 14 and crosses over the gate wire 16 is formed. The section of the gate wire 16 that is disposed opposite of the organic semiconductor layer 28, via the gate insulator 26, forms the gate electrode 16a.

As formation material (functional liquid) of the organic semiconductor layer, for example, polymeric organic semiconductor materials, fullerene (C60), metallophthalocyanine and substituted derivatives thereof, acene molecular materials, α-oligothiophene, and PQT 12 (or 12 PQT; PQT is polyquaterthiopene) can be used. One type among these can be used. Alternatively, two or more types can be used in combination. The polymeric organic semiconductor material is, for example, fluorine-bithiophene copolymer, such as poly(3-alkylthiphene), poly-3-hexylthiophene [P3HT], poly(3-octylthiophene), poly(2,5-thienylene vinylen) [PTV], poly(p-phenylenevinylene) [PPV], poly(9,9-dioctylfluorene) [PFO], poly(9,9-dioctylfluorene)-co-bis-N,N′-(4-Methoxyphenyl)-bis-N,N′-(phenyl-1,4-phenylenediamine) [PFMO], poly(9,9-dioctylfluorene-co-benzothiadiazole) [BT], fluorine triallylamine copolymer, triallylamine polymer, and poly(9,9-dioctylfluorene-co-dithiophene) LF8T2]. Acene molecular material is, for example, anthracene, tetracene, pentacene, and hexacene. Specifically, α-oligothiophene is a low molecular organic semiconductor, such as quaterthiophene (4T), sexithiophene (6T), and octylthiophene.

Before the organic semiconductor layer 28 is formed, the surface to become the base of the organic semiconductor layer 28 or, in other words, the surface of the gate insulator 26 on the substrate 1 can be processed for modification to successfully form the organic semiconductor layer 28. The surface modification process is, for example, a surface treatment using a surface modification agent, an organic cleaning process, an alkali treatment, a UV ozone treatment, a fluoridation treatment, a plasma treatment, and a Langmuir-Blodgett film formation process. One process or two or more processes, among the processes, can be used. The surface modification agent is, for example, hexamethylene disilazane, cyclohexane, and octadecyl trichloromonosilane. The organic cleaning process uses acetone, isopropyl alcohol, and the like. The alkali treatment involves acids, such as hydrochloric acid, sulfuric acid, and acetic acid, sodium hydroxide, potassium hydroxide, calcium hydrate, and ammonia.

After the organic semiconductor layer 28 is formed, the conductive functional liquid is discharged onto the capacitor wire formation area 20 by the droplet dischargeion device IJ. A capacitor wire 29, shown in Fig.), is formed. As a conductive particle included in the conductive functional liquid, metal particles including any of, for example, gold, silver, copper, palladium, manganese, and nickel are used. In addition to the metal particles, oxides of the metal particles, conductive polymer and superconductive particles, and the like are used. According to the embodiment, the conductive particle is gold.

As a result of the above-described procedures, a capacitor 30 is formed. The capacitor 30 has a laminated structure in which the pixel electrode 13, the first inter-layer insulator 27, and the capacitor wire 29 are layered. The capacitor 30 is used to hold the electric charge of the pixel electrode 13. Data can be held in each pixel area of the electrophoretic device 100.

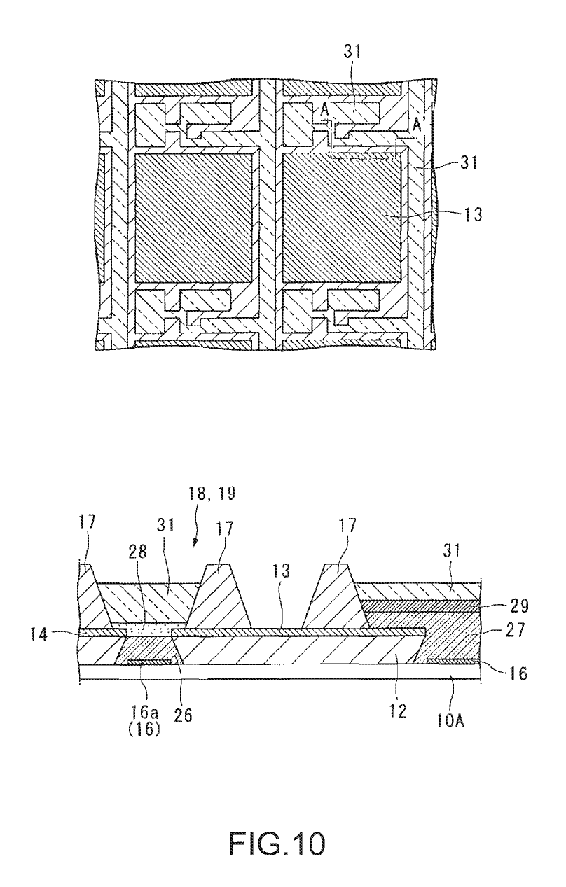

Next, in all areas partitioned by the second partition 17 (the gate insulator formation area 18, the semiconductor layer formation area 19, and the capacitor wire formation area 20), a second inter-layer insulator 31 is formed using the droplet discharging device IJ. The second inter-layer insulator 31 is formed from the same material as the gate insulator 26 and the first inter-layer insulator 27. The TFT substrate 10 forming the electrophoretic device 100, as shown in FIG. 10, is formed by the above-described procedure.

Therefore, the electrophoretic device (electro-optic device) 100 according to the embodiment includes the substrate main body 10A, the first partition 12, the gate electrode 16a, the signal line 14, the pixel electrode 13, and the second partition 17. The first partition 12 is provided on the substrate main body 10A. The gate electrode 16a is provided in a groove formed by the first partition 12. The signal line 14 and the pixel electrode 13 are provided on the top surface of the first partition 12. The second partition 17 provided on the first partition 12. The gate insulator 296 is provided within the groove. The electrophoretic (photoelectric device) device 100 also includes an organic semiconductor layer 28 formed by the droplet dischargeion method in the semiconductor layer formation area 19. The semiconductor layer formation area 19 is surrounded by the second partition 17. The organic semiconductor layer 28 crosses over the gate electrode 16a and electrically connects the signal line 14 and the pixel electrode 13. The organic semiconductor layer 28 forms an organic TFT 60 of the electrophoretic device 100, as described hereafter.

Next, the TFT substrate 10 and an opposing substrate 32 are laminated by a frame-shaped sealing component (not shown) so as to surround the display area. A spacer (not shown) is used to maintain a constant distance between the TFT substrate 10 and the opposing substrate 32. A microcapsule 70 serving as an electro-optic layer is held between the TFT substrate 10 and the opposing substrate 32. As a result, the electrophoretic device 100 shown in FIG. 11 can be formed. The microcapsule 70 is an electrophoretic dispersing liquid 40 that has been formed into a microcapsule by being coated with a resin film in a capsule form. The electrophoretic dispersing liquid 40 includes carrier fluid 41, electrophoretic particles 42 and the like

The opposing substrate 32 is formed from a flexible, transparent material, such as resin film substrate. A shared electrode 33 is formed on a side on which the inner side of the opposing substrate 32 (microcapsule 70) is disposed.

Next, the electrophoretic dispersing liquid 40 forming the microcapsule 70 will be described. In the electrophoretic dispersing liquid 40, the electrophoretic particles 42 are dispersed within the carrier fluid 41 that is dyed using dye. The electrophoretic particle 42 is a roughly spherical particle with a diameter of about 0.01 μm to 10 μm. The particle is formed from inorganic oxide or inorganic hydroxide. The particle has a color (including white and black) that differs from that of the carrier fluid 41. In this way, the electrophoretic particles 42 formed from an oxide or a hydroxide has a unique surface isoelectric point. Surface electric charge density (charge) thereof changes depending on the hydrogen ion exponent pH of the carrier fluid 41.

Here, the surface isoelectric point is a state in which an algebraic sum of the electric charges of the ampholyte in the aqueous solution is zero, expressed by hydrogen ion exponent pH. For example, when the pH of the carrier fluid 41 is equal to the surface isoelectric point of the electrophoretic particle 42, the effective charge of the electrophoretic particle 42 becomes zero. The electrophoretic particle 42 is unresponsive to the external electric field. When the pH of the carrier fluid 41 is lower than the surface isoelectric point of the electrophoretic particle 42, the surface of the electrophoretic particle 42 become electrified with a positive electric charge by a reaction formula (1), below. On the other hand, when the pH of the carrier fluid 41 is higher than the surface isoelectric point of the electrophoretic particle 42, the surface of the electrophoretic particle 42 become electrified with a negative electric charge by a reaction formula (2), below.

Low pH: ROH+H⁺(excess)+OH⁻→ROH₂⁺ (1)

High pH: ROH+OH⁻(excess)→RO⁻+H₂O (2)

When the difference between the pH of the carrier fluid 41 and the surface isoelectric point of the electrophoretic particle 42 is widened, the charge of the electrophoretic particle 42 increases in accordance to the reaction formula (1) or (2). However, when the difference is equal to or more than a predetermined value, the charge is roughly saturated. The charge does not change even when the pH is further changed. The value of the difference differs depending on the type, size, shape, and the like of the electrophoretic particle 42 However, generally, if the value is 1 or more, the charge is thought to be roughly saturated regardless of the details of the electrophoretic particle 42.

As the above-described electrophoretic particle 42, for example, titanium dioxide, zinc oxide, magnesium oxide, red oxide, aluminum oxide, black titanium oxide, chrome oxide, boehmite, FeOOH, silicon dioxide, magnesium hydroxide, nickel hydroxide, zirconium oxide, and copper oxide can be used.

The electrophoretic particles 42 such as this can be used not only as individual particles, but also in a state in which various surface modifications have been performed. As such surface modification methods, the following methods can be used. For example, the particle surface can undergo a coating process using polymers, such as acrylic resin, epoxy resin, polyester resin, and polyurethane resin. Alternatively, the particle surface can undergo a coupling process using, for example, a silane coupling agent, a titanate coupling agent, an aluminum coupling agent, or a fluorine coupling agent. Alternatively, the particle surface can undergo a graft polymerization process with, for example, an acrylic monomer, a styrene monomer, an epoxy monomer, or an isocyanate monomer. The processes can be performed independently or in a combination of two or more types.

A nonaqueous organic solvent, such as hydrocarbon, halogenated hydrocarbon, and ether is used in the carrier fluid 41. The nonaqueous organic solvent is colored with dyes such as Spirit Black, Oil Yellow, Oil Blue, Oil Green, Valifast Blue, Macrolex Blue, Oil Brown, Sudan Brown, and Fast Orange. The nonaqueous organic solvent is of a color differing from that of the electrophoresis particles 42.

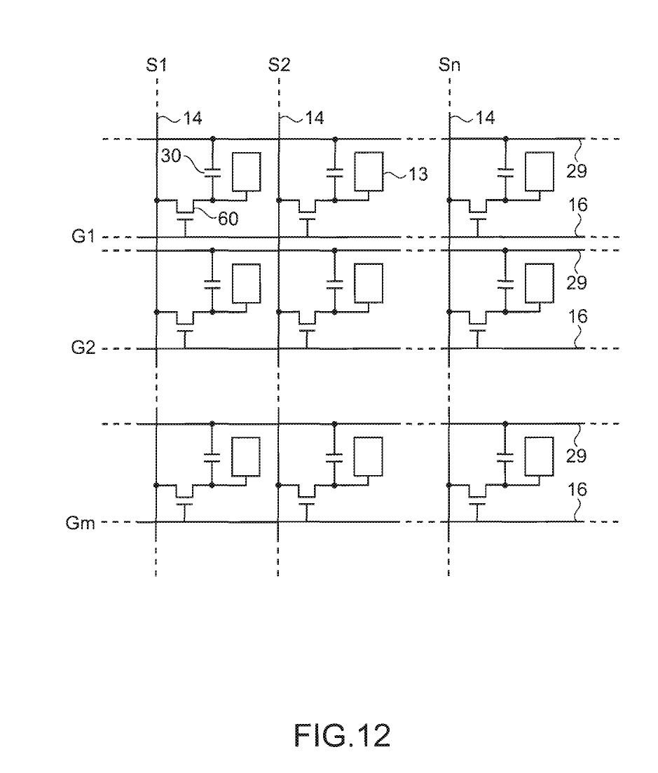

FIG. 12 is a diagram of an equivalent circuit of a plurality of dots disposed in the form of a matrix forming the image display area of the electrophoretic device 100. In the electrophoretic device 100 according to the embodiment, a pixel electrode 13 and an organic TFT 60 are formed on each of the plurality of pixels disposed in the form of a matrix forming the image display area, as shown in FIG. 12. The organic TFT 60 is a switching element for controlling the pixel electrode 13. The signal line 14 to which the image signal is supplied is electrically connected to the source of the organic TFT 60. Image signals S1, S2, . . . , Sn written to the signal line 14 are sequentially supplied to the signal line 14. Alternatively, the image signals are supplied per group to a plurality of signal lines 14 that are adjacent to each other. The gate wire 16 is electrically connected to the gate of the organic TFT 60. Scanning signals G1, G2, . . . , Gm are successively applied in a pulse-like manner to a plurality of gate wires 16, at a predetermined timing. The pixel electrode 13 is electrically connected to the drain of the organic TFT 60. By the organic TFT 60 that is the switching element being turned ON for only a certain amount of time, the image signals S1, S2, . . . , Sn supplied from the signal line 14 are written at a predetermined timing.

The image signals S1, S2, . . . , Sn of a predetermined level that are written to the dispersing liquid via the pixel electrode 13 is held for a certain amount of time between the pixel electrode 13 and the shared electrode 33 provided on an opposing substrate 35. The electrophoretic particles 42 move within the carrier fluid 41 as a result of the applied voltage and gather on either one of the pixel electrode 13 and the shared electrode 33, thereby modulating the light. According to the embodiment, to prevent the charge of the pixel electrode or, in other words, the held image signal from leaking, a capacitor 30 that serves as a storage capacitor in addition to the pixel capacitor is formed between the pixel electrode 13 and the shared electrode 33.

In the electrophoretic device 100 configured as described above and the manufacturing method thereof, the functional liquid discharged onto the semiconductor layer formation area 19 can be self-flowing (capillarity). The functional liquid can be allowed to flow into the ends of a fine pattern. Therefore, the channel length in the organic semiconductor layer 28 that intersects with the gate electrode 16 can be shortened. The gate electrode (gate wire) does not intersect (gate overlap) with the source and the drain as does in the conventional structure, and parasitic capacitance can be prevented. Therefore, a highly reliable electrophoretic device 100 in which problems such as wiring delays are prevented can be obtained. The capacitor 30 that holds the charge of the pixel electrode 13 is formed. Therefore, a highly reliable electrophoretic device 100 in which the leak of the held image signal (data) is prevented can be obtained.

Liquid Crystal Device

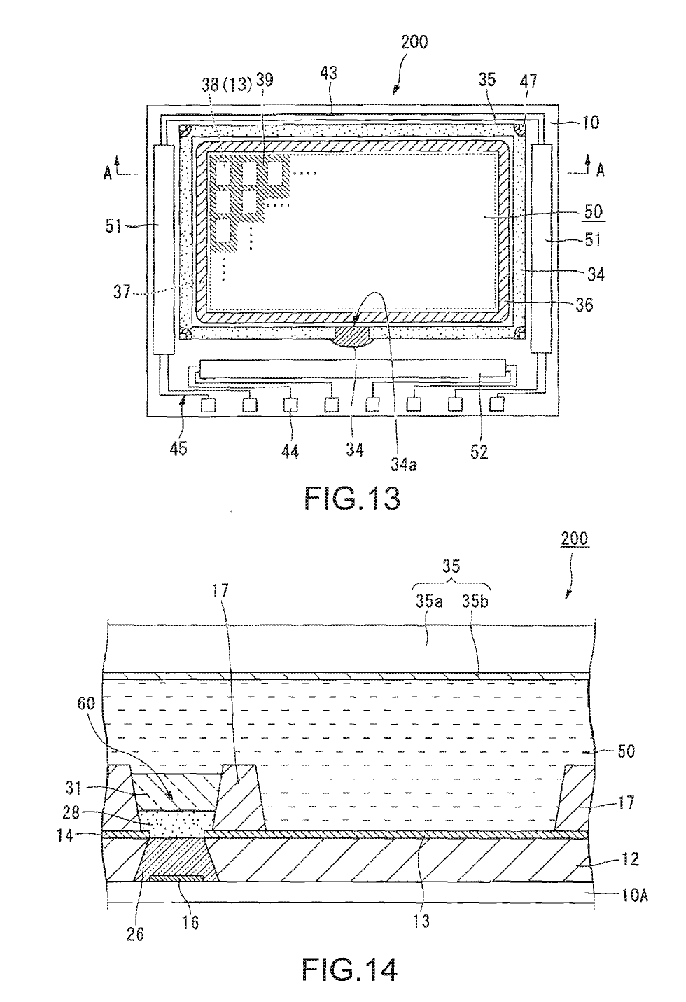

Next, an electro-optic device according to another embodiment and a liquid crystal display according to an embodiment of the invention will be described. The liquid crystal device 200 includes the above-described TFT substrate 10. A liquid crystal layer 50 is sandwiched between the TFT substrate 10 and the opposing substrate 35 disposed opposite of the TFT substrate 10. FIG. 13 is a diagram showing an overall configuration of the liquid crystal device 200. As shown in FIG. 13, in the liquid crystal device 200, the TFT substrate 10 and the opposing substrate 35 that are disposed opposing each other are adhered together by a sealing material 34. The liquid crystal layer 50 is formed within the area partitioned by the sealing material 34. According to the embodiment, Al is used as the material forming the pixel electrode 13. In other words, the liquid crystal device 200 according to the embodiment is suitably used as a reflective liquid crystal device.

An inlet 34a in which the liquid crystal is injected is provided oil a section of the sealing material 34. The inlet 34a is sealed by a sealing agent 34b. A light-shielding film (perimeter separator) 36 made from light-shielding material is formed in the inner area of the sealing material 34. The area within the perimeter separator 36 is a light modulation area in which the light is modulated. In the light modulation area 37, a plurality of pixel areas 38 are provided in the form of a matrix. Near each pixel area 38, a black matrix 39 made from a light-shielding material is provided in the form of a lattice. The black matrix is formed so as to cover the second partition 17 and the second inter-layer insulator 31 on the TFT substrate 10. The pixel electrode 13 is faces the bottom surface of each pixel area 38.

The periphery of the TFT substrate 10 is a projecting area projecting from the opposing substrate 35. A scanning line driving circuit 51 that generates a scanning signal is formed within the projecting area, on the left side and the right side in the diagram. A wiring 43 connected between the left and right scanning line driving circuits 51 is laid along the upper side in the diagram. A data line driving circuit 52 that generates a data signal and a connecting terminal 44 for connecting to an external circuit and the like are formed on the lower side in the diagram. In the area between the scanning line driving circuit 51 and the connecting terminal 44, a wiring 45 connecting the scanning line driving circuit 51 and the connecting terminal 44 is formed. An inter-substrate conducting material 47 for electrically connecting the TFT substrate 10 and the opposing substrate 35 is provided in each corner of the opposing substrate 35.

A pixel signal of the predetermined level written to the liquid crystal via the pixel electrode 13 is held for a certain amount of time between the pixel electrode 13 and the shared electrode 35b of the opposing substrate 35. However, the pixel signal can be prevented from leaking by the capacitor 30 provided in the TFT substrate 10. For example, the voltage of the pixel electrode 13 is held in the capacitor 30 for an amount of time longer by three digits than the time during which the source electrode is applied. The holding characteristics of the electric charge are modified, and a liquid crystal device 200 with a high contrast ratio can be actualized.

FIG. 14 is a schematic diagram of a cross-section taken along line A-A in FIG. 13. As shown in FIG. 14, the TFT substrate 10 includes the substrate main body 10A made from a material with high light transmittance, such as glass and quartz. The substrate main body 10A includes the pixel electrode 13 on the liquid crystal side and the organic TFT 60. The organic TFT 60 supplies the pixel electrode 13 with electric signals. An oriented film (not shown) is formed so as to cover the pixel electrode 13.

As does the TFT substrate 10, the opposing substrate 35 is formed with a base material 35 serving as the main body. The base material 35 is made from a material with high light transmittance, such as glass and quartz. A shared electrode 35b is formed on the inner surface (liquid crystal layer 50 side) of the base material 35a. An oriented film (not shown) is formed on the shared electrode 35b. The liquid crystal device according to the embodiment is a reflective type. Therefore, the shared electrode 35b is formed from a transparent conducting material, such as ITO. In the liquid crystal device 200, the retardation film and the polarizing film are disposed in predetermined directions depending on the type of liquid crystal 50 to be used, or in other words, depending on the operation mode and whether the mode is normally white mode or normally black mode. The operation modes are, for example, twisted nematic (TN) mode, compensated TN (CTN) mode, vertical alignment (VA) technique, and in-plane switching (IPS) technique.

In the liquid crystal device 200 according to the embodiment, the gate length is short as in the electrophoretic device 100 according to the above-described embodiment. Problems such as writing delays caused by gate overlapping can be prevented. As a result, a liquid crystal device 100 that is highly reliable, has high contrast ratio, and has high display quality can be obtained.

Organic EL Device

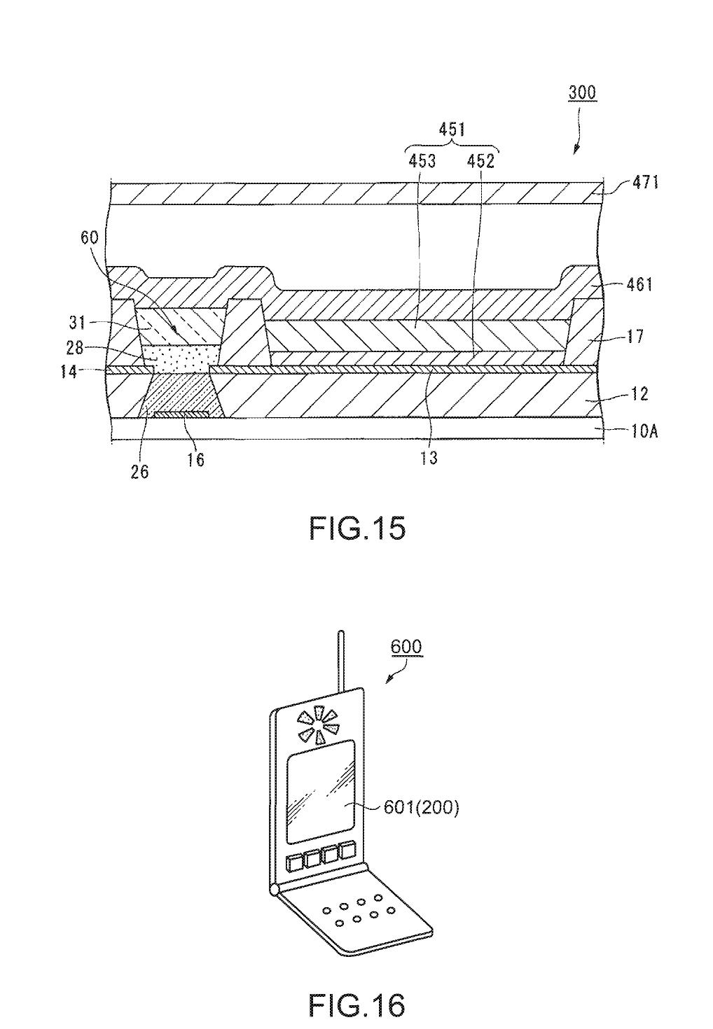

Next, the electro-optic device according to another embodiment and an organic electroluminescent device (referred to, hereinafter, as an organic EL device) according to an embodiment of the invention will be described. FIG. 15 is a cross-sectional view of a configuration of the organic EL device.

In an organic EL device 300, a light-emitting element 451 is formed on the pixel electrode 13. The pixel electrode 13 faces the inside of a concave opening (pixel area) formed by the second partition 17 provided on the TFT substrate 110. The light-emitting element 451 is an element emitting red-colored light, an element emitting green-colored light, or an element emitting blue-colored light provided in each pixel area. As a result, the organic EL device 300 can actualize full-color display. A cathode 461 is formed on the entire surface of the top of a bank section 441 and the light-emitting electrode 451. A sealing substrate 471 is laminated over the cathode 461.

The manufacturing process for manufacturing an organic EL device 401 including an organic EL element includes a plasma processing procedure, a light-emitting element forming procedure, an opposing electrode forming procedure, and a sealing procedure. The plasma processing procedure is performed to suitably form the light-emitting element 451. The light-emitting element forming procedure forms the light-emitting element 451. The opposing electrode forming procedure forms the cathode 461. The sealing procedure laminates the sealing substrate 471 over the cathode 461 and seals the cathode 461.

A light-emitting element forming procedure forms a hole injection layer 452 and a light-emitting layer 453 on the pixel electrode 113 facing the pixel area and forms the light-emitting element 451. The hole injection layer forming procedure includes an discharging procedure and a drying procedure. The discharging procedure discharges a liquid material used to form the hole injection layer 452 onto each pixel electrode 13. The drying procedure dries the discharged liquid material and forms the hole injection layer 452.

The light-emitting layer forming procedure includes an discharging procedure and a drying procedure. The discharging procedure discharges a liquid material used to form the light-emitting layer 453 onto the hole injection layer 452. The drying procedure dries the discharged liquid material and forms the light-emitting layer 453. As described above, three types of light-emitting layers 453 are formed from materials corresponding to three colors: red, green, and blue. Therefore, the discharging procedure for the light-emitting layer 453, described above, includes three procedures performed to respectively discharge the three types of materials. In the light-emitting element forming procedure, the droplet discharging device IJ can be used when the hole injection layer 452 is formed and when the light-emitting layer 453 is formed.

In the organic EL device 300 according to the embodiment as well, the gate length is short, as in the electrophoretic device 100 and the liquid crystal device 200 according to the above-described embodiments. The organic EL device 300 also includes a highly reliable organic TFT 65. As a result, an organic EEL device 300 that has high display quality can be obtained.

Electrical Apparatus

Next, an electrical apparatus of the invention will be described in detail.

FIG. 16 is a perspective view of an example of a portable phone. In FIG. 16, reference number 600 indicates the main body of the portable phone. Reference number 601 indicates a liquid crystal display section including the liquid crystal display device according to the above-described embodiment.

The electrical apparatus shown in FIG. 16 includes the above-described liquid crystal device 200. Therefore, high quality and high performance can be achieved.

The electrical apparatus according to the embodiment includes the above-described liquid crystal device 200. However, the electrical apparatus can include the organic EL device 300 or the electrophoretic device 100.

In addition to the above-described electrical apparatus, the present invention can be applied to various electrical apparatus, such as a liquid crystal projector, a multi-media personal computer (PC), an engineering workstation (EWS), a pager, a word processor, a television, a view-finder-type or a direct-view-monitor-type video tape recorder, an electronic organizer, an electronic calculator, a car navigation device, a point of sale (POS) terminal, and a device including a touch panel.

Exemplary embodiments of the present invention have been described with reference to the accompanying drawings. However, it goes without saying that the invention is not limited thereto. The configuration, combinations, and the like of each constituent component are examples. Various modifications based on design requests and the like can be made without departing from the scope of the invention.

1. An electro-optic device manufacturing method comprising:
providing a first partition on a substrate in a form of a pattern;
depositing a metal material onto the substrate, forming a pixel electrode and a signal line on a top surface of the first partition, and forming a gate wire in an area surrounded by the first partition:
after depositing, forming a second partition that partitions at least the a gate insulator formation area and a semiconductor layer formation area of which a section overlaps with the gate insulator formation area on the substrate;
discharging functional liquid including a formation material for forming an insulator layer in the gate insulator formation area and forming a gate insulator; and
after forming the gate insulator, discharging a functional liquid including a formation material for forming an organic semiconductor layer onto the semiconductor formation area and forming an organic semiconductor layer that crosses over the gate electrode and a section of the gate insulator and electrically connects the pixel electrode and the signal line.

2. The electro-optic device manufacturing method according to claim 1, wherein an auxiliary wiring is formed on at least one area of a surface of the substrate on which the gate wire is formed, before the first partition is formed.

3. The electro-optic device manufacturing method according to claim 1, wherein:
when forming the second partition, the second partition is partitioned and formed so as to face a portion of the pixel electrode, and a capacitor wire formation area included in a capacitor that holds an electric charge of the pixel electrode is formed;
when forming the gate insulator, the functional liquid is also discharged onto the capacitor wire formation area, and an inter-layer insulator included in the capacitor is formed; and
after forming the organic semiconductor layer, conducting functional liquid is discharged onto the capacitor wire formation area, forming the capacitor, and the capacitor having a laminated structure in which the pixel electrode, the inter-layer insulator, and the capacitor wire are layered is formed.

4. The electro-optic device manufacturing method, according to claim 3, wherein:
a liquid pooling section that is wider than those of other areas is provided in at least one area among the gate insulator formation area, the semiconductor layer formation area, and the capacitor wire formation area, and the functional liquid is discharged onto the liquid pooling section.

5. The electro-optic device manufacturing method according to claim 1, wherein:
an inner wall of the first partition forming an area in which the gate wire is formed is an angled surface that forms an acute angle to a top surface of the substrate.

6. An electro-optic device comprising:
a substrate, a first partition provided on the substrate, a gate electrode provided in a groove formed by the first partition, a gate insulator covering the gate electrode, a signal line and a pixel electrode provided on a top surface of the first partition, and a second partition provided on the first partition so as to cross over a section of the groove,
wherein, an organic semiconductor layer that crosses over the gate insulator, electrically connects the signal line and the pixel electrode, and is formed by a droplet discharging method is provided in a semiconductor layer formation area surrounded by the second partition.

7. The electro-optic device according to claim 5, wherein:
a capacitor that holds the electric charge of the pixel electrode is formed in an area surrounded by the second partition; and
the capacitor includes a capacitance electrode formed from a portion of a capacitor wire and a portion of the pixel electrode and an insulator layer, and an insulator layer provided between capacitance electrodes.

8. The electro-optic device according to claim 5, wherein:
a liquid pooling section that is wider than those of other areas is formed in a section of the semiconductor layer formation area.

9. An organic electroluminescent device in which an organic light-emitting layer is provided between a pair of electrodes provided on a substrate, the organic electroluminescent device comprising:
a first partition, a gate electrode disposed in a groove formed by the first partition, a signal line and a pixel electrode provided on a top surface of the first partition, and a second partition laminated onto the first partition,
wherein, in one area surrounded by the second partition, an organic semiconductor layer that crosses over a gate insulator covering the gate electrode and electrically connects the signal line and the pixel electrode is provided, and
in another area surrounded by the second partition, the insulator layer and the capacitance electrode are laminated onto the pixel electrode, thereby forming a capacitor that holds the electric charge of the pixel electrode.

10. An electronic apparatus comprising the electro-optic device according to claim 6.

11. An electronic apparatus comprising the electro-optic device according to claim 7.

12. An electronic apparatus comprising the electro-optic device according to claim 8.

13. An electronic apparatus comprising the organic electroluminescent device according to claim 9.
